(19) United States
(12) Patent Application Publication
(10) Pub. No.: US 2001/0016302 A1
(43) Pub. Date: Aug. 23, 2001

(54) Wafer chucks allowing controlled reduction of substrate heating and rapid substrate exchange

(75) Inventors: Noriyuki Hirayanagi, Kawasaki-shi (JP); Hajime Yamamoto, Kawasaki-shi (JP); Tomoharu Fujiwara, Ageo-shi (JP)

Correspondence Address: KLARQUIST SPARKMAN CAMPBELL LEIGH & WHINSTON, LLP, One World Trade Center, Suite 1600, 121 S.W. Salmon Street, Portland, OR, 97204-2988, US

(73) Assignee: Nikon Corporation

(21) Appl. No.: 09/749,865

(22) Filed: Dec. 27, 2000

(30) Foreign Application Priority Data
Dec. 28, 1999 (JP) 11-373333
Dec. 28, 1999 (JP) 11-373162
Jan. 13, 2000 (JP) 2000-004211

(51) Int. Cl. G03F 7/00; G03C 5/00

(52) U.S. Cl. 430/322; 430/311

(57) ABSTRACT

Substrate-holding devices (“wafer chucks”) and methods are disclosed for use in any of various apparatus and methods for processing a substrate. For example, the wafer chucks are especially useful with microlithography apparatus and methods, especially such apparatus and methods employing a charged particle beam. The devices and methods achieve controlled reduction of substrate heating and rapid substrate exchange during substrate processing. The wafer chuck has an adhesion surface and a heat-transfer-gas (HTG) channel. In an exemplary configuration, the HTG channel is connected to an HTG supply and a gas-evacuation system. Heat-transfer gas is caused to flow through the channel during a predetermined time period when the substrate is being held (typically by electrostatic force) on the adhesion surface. At a first time instant, execution of the fabrication process on the substrate (adhered to the adhesion surface) is commenced. At a second time instant relative to the fabrication process, the heat-transfer gas is evacuated from the channel. These time instants can be established to allow wafer-exchange to be performed quickly.

### FIELD OF THE INVENTION

This invention pertains to microlithography (transfer of a pattern, defined on a reticle or mask, onto a sensitive substrate). Microlithography is a key technology used in the fabrication of semiconductor integrated circuits, displays, and the like. More specifically, the invention pertains to substrate-holding devices (termed “wafer chucks”), to which the substrate (“wafer”) is mounted, that hold the substrate during microlithographic exposure. Even more specifically, the invention pertains to wafer chucks that remove heat from the wafer-mounting surface of the wafer chuck and that are configured to exchange wafers rapidly as successive wafers are exposed, so as to provide improved throughput.

### BACKGROUND OF THE INVENTION

During microlithographic exposure of a sensitive substrate (“wafer”) the wafer typically is mounted to and held by a “wafer chuck.” Microlithography performed using a charged particle beam must be performed in a subatmospheric pressure (“vacuum” environment); hence, the wafer chuck must be capable of holding the wafer in such an environment. Most conventional wafer chucks intended for use in a vacuum environment are configured to hold the wafer using electrostatic force. The surface of the wafer chuck to which the wafer (i.e., the downstream-facing surface of the wafer) is mounted is termed the “adhesion surface” of the chuck.

During exposure of a wafer using a charged particle beam, the exposure beam is incident with high energy on the “sensitive” surface (upstream-facing resist-coated surface) of the wafer. Consequently, the wafer tends to experience heating, which can cause undesired thermal expansion of the wafer. Thermal expansion of the wafer can degrade the accuracy with which a pattern is transferred to the sensitive surface. Under extreme circumstances of wafer heating, the wafer can detach from or shift position on the adhesion surface.

One conventional method of reducing wafer heating is to configure the adhesion surface with grooves or channels that define a gap between the adhesion surface and the downstream-facing surface of the wafer. A heat-transfer gas such as helium is conducted through the channels, whenever the wafer is mounted to the adhesion surface, to dissipate heat from the wafer. Hence, the channels are termed herein “heat-transfer-gas channels” or “HTG channels.”

A disadvantage of the conventional scheme noted above is the propensity of the heat-transfer gas to leak from the HTG channels into the vacuum chamber whenever a wafer currently mounted to the chuck is being removed for replacement with a new wafer. The consequent release of the heat-transfer gas into the vacuum chamber causes a temporary disruption of the vacuum level inside the lens column of the microlithography apparatus. These disruptions of the vacuum level reduce the overall stability of the microlithography apparatus. To reduce the vacuum-disrupting effect, it is necessary to evacuate the heat-transfer gas from the HTG channels for a sufficient time before the processed wafer is removed from the wafer chuck. Evacuation must continue until the vacuum level in the HTG channels is substantially the same (within a specified tolerance) as in the vacuum chamber. Then, the current wafer can be removed from the adhesion surface and replaced with a new wafer. Unfortunately, this gas-evacuation step requires time to execute and hence reduces throughput.

The time required to perform evacuation of the heat-transfer gas from the HTG channels can be substantial (e.g., 15 seconds). The long time is a result of various causes, including the fact that the HTG channels typically are very narrow. Narrow channels normally require considerable time to evacuate by conventional methods.

In addition, trace amounts of impurities (e.g., H₂O, contaminant gases, etc.) typically are present in the conduits through which the heat-transfer gas is supplied to the HTG channels between the wafer and the adhesion surface. Also, trace amounts of impurities typically are present in the heat-transfer gas itself. H₂O (water vapor) is a problem because the presence of this gas prevents increasing the vacuum in the vacuum chamber to a desired level. An exemplary contaminant gas is CO₂, which tends to precipitate solid contaminants such as carbon and organic substances inside the vacuum chamber, especially on electromagnetic lenses and the like through which the charged particle beam passes as the beam propagates through the lens column of the microlithography apparatus. These contaminants can have any of various adverse effects. For example, contaminant deposits in the column can become charged electrostatically as they encounter charged particles of the beam. The charged deposits can impart an undesired deflection of the charged particle beam as the beam propagates through the column. In general, these adverse affects tend to reduce the accuracy of pattern transfer.

Again, to prevent or reduce problems associated with these contaminants, it is necessary to evacuate the HTG channels between the wafer and the adhesion surface of the wafer chuck for a sufficient time before exchanging wafers. As noted above, the channel-evacuation time tends to reduce throughput. Also, evacuated and used heat-transfer gas (which is expensive) conventionally is discarded, resulting in increased operating expense of the microlithography apparatus.

### SUMMARY OF THE INVENTION

In view of the disadvantages of conventional wafer chucks as summarized above, an object of the invention is to provide substrate-holding devices (generally termed herein “wafer chucks”) configured to allow rapid exchange of wafers while the wafer chuck is at the wafer-exchange position. Another object is to provide wafer chucks that facilitate the attainment of improved throughput, compared to conventional apparatus.

To such ends, and according to one aspect of the invention, substrate-holding devices are provided that are configured to hold a substrate while a fabrication process is being performed on the substrate. An embodiment such a substrate-holding device comprises a wafer-chuck body defining an adhesion surface and including an electrostatic electrode. The adhesion surface is configured to contact a downstream-facing surface of a substrate being held to the substrate-holding device by an electrostatic force generated by the electrode. The adhesion surface defines a channel configured, whenever the substrate is adhered to the adhesion surface by the electrostatic force, to provide a conduit for a heat-transfer gas that, when in the channel, contacts and removes heat from the downstream-facing surface of the substrate. The substrate-holding device of this embodiment also includes a gas-supply conduit, a gas-evacuation conduit, and a controller. The gas-supply conduit is configured to conduct the heat-transfer gas from a source to the channel in a controllable manner. The gas-evacuation conduit is configured to conduct the heat-transfer gas from the channel in a controllable manner. The controller is configured to: (a) cause the heat-transfer gas to flow through the channel from the gas-supply conduit during a predetermined time period when the sensitive substrate is being held on the adhesion surface, (b) at a first predetermined time instant, commence execution of the fabrication process on the substrate being held on the adhesion surface, and (c) at a second predetermined time instant relative to the fabrication process, commence evacuating the heat-transfer gas from the channel. The controller also can be configured to determine, in advance of executing the fabrication process, an expected length of an evacuation time period required to evacuate the heat-transfer gas from the channel, and to set the second predetermined time instant based on the determined expected length of the evacuation time period. The controller also can be configured to determine the second predetermined time instant as occurring before commencing an exchange, on the adhesion surface, of a new substrate for an already processed substrate. The controller also can be configured to establish the second predetermined time instant as occurring at an instant when the fabrication process executed on the substrate on the adhesion surface is at least 80% complete.

A representative heat-transfer gas is helium. In such an instance, the controller can be configured to establish a target pressure of the heat-transfer gas in the channel of no greater than 2.7 kPa (20 Torr).

According to another aspect of the invention, substrate-processing apparatus are provided that include a substrate-holding device according to any of various embodiments of the invention.

According to another aspect of the invention, microlithography apparatus are provided. An embodiment of such an apparatus comprises an exposure-optical system, a wafer chuck, a gas-supply conduit, a gas-evacuation conduit, and a controller. The exposure-optical system is situated and configured to form an image, on a sensitive substrate, of a pattern using an energy beam. The wafer chuck comprises an adhesion surface defining a channel for heat-transfer gas. The wafer chuck is configured to hold, as the sensitive substrate is being exposed by the energy beam, a downstream-facing surface of the sensitive substrate in contact with the adhesion surface. General features of the wafer chuck can be similar to the substrate-holding device summarized above. The microlithography apparatus can further comprise a vacuum chamber enclosing and providing a subatmospheric-pressure environment for the exposure-optical system and the wafer chuck. The controller can be further configured to perform one or more of the following: (a) determine, in advance of the exposure, an expected length of an evacuation time period required to evacuate the heat-transfer gas from the channel, and to set the second predetermined time instant based on the determined expected length of the evacuation time period; (b) determine the second predetermined time instant as occurring before commencing an exchange, on the wafer chuck, of a new substrate for an already-exposed substrate; (c) establish the second predetermined time instant as occurring at an instant when microlithographic exposure of the substrate on the wafer chuck is at least 80% complete; and (d) especially if the heat-transfer gas is helium, establish a target pressure of the heat-transfer gas in the channel of no greater than 2.7 kPa (20 Torr).

Another aspect of the invention is directed, especially in the context of microlithography methods, to methods for reducing exposure-induced thermal deformation of the substrate. According to an embodiment of such a method, a wafer chuck is provided that is configured according to any of the wafer-chuck embodiments within the scope of the invention. A sensitive substrate is mounted to the adhesion surface of the wafer chuck such that the downstream-facing surface of the substrate contacts the adhesion surface and encloses the channel. A heat-transfer gas is introduced into the channel such that the heat-transfer gas flowing through the channel contacts the downstream-facing surface of the substrate. Microlithographic exposure of the sensitive substrate, mounted to the wafer chuck, is commenced. An appropriate time instant is determined and set, during the microlithographic exposure, in which to commence evacuation of the heat-transfer gas from the channel in preparation for wafer-exchange. At the set time instant, evacuation of the heat-transfer gas from the channel is commenced.

Another embodiment of a wafer chuck according to the invention comprises an electrode situated and configured to attract the sensitive substrate by electrostatic attraction such that the substrate is held on the wafer chuck with the downstream-facing surface contacting the adhesion surface, thereby enclosing the channel. The wafer chuck includes an HTG-inlet port situated and configured to introduce a heat-transfer gas into the channel to contact with the downstream-facing surface of the substrate mounted to the adhesion surface. The wafer chuck also includes a gas-evacuation port situated and configured to allow evacuation of heat-transfer gas from the channel, and a valve mounted to the wafer chuck. The valve is configured to open and close at least one of the inlet port and the evacuation port. The wafer chuck desirably also includes a controller connected to the valve, wherein the controller is configured to open and close the valve as required to cause heat-transfer gas to flow through the channel and to stop flow of heat-transfer gas through the channel at respective appropriate times.

A substrate-processing apparatus (e.g., microlithography apparatus), according to the invention comprises a wafer chuck according to any of the various embodiments. The wafer chuck is used to hold a sensitive substrate as a pattern is being exposed onto the sensitive substrate. The apparatus also includes a movable wafer stage to which the wafer chuck is mounted. By way of example, the wafer chuck can include an HTG-inlet port, a gas-evacuation port, and a valve mounted to the wafer chuck or the wafer stage, wherein the valve is configured to open and close at least one of the inlet port and the evacuation port. The apparatus also can include a vacuum chamber configured to be evacuated so as to produce a vacuum environment inside the vacuum chamber. In such a configuration, the wafer stage and wafer chuck are located inside the vacuum chamber.

If the valve is configured to open and close the HTG-inlet port, the apparatus can include an HTG source connected via an HTG-supply conduit to the HTG-inlet port. The apparatus also can include an exhaust pump connected to the HTG-supply conduit, wherein the exhaust pump is configured to reduce the pressure in the HTG-supply conduit. The apparatus desirably also includes a pressure sensor connected to the HTG-supply conduit, wherein the pressure sensor is configured to measure the pressure in the HTG-supply conduit. The apparatus desirably also includes a controller connected to the first valve, the exhaust pump, and the pressure sensor. Such a controller can be configured to actuate the first valve in a controllable manner to introduce the heat-transfer gas into the channel when needed to remove heat from the substrate, and to actuate the exhaust pump to draw the heat-transfer gas from the channel in anticipation of substrate-exchange.

The apparatus also can include a second valve associated with the gas-evacuation port. In such a configuration, the apparatus can include a gas-evacuation conduit connected to the gas-evacuation port, wherein the controller is connected to the first and second valves and is configured to close the second valve after supplying heat-transfer gas through the HTG-inlet port to the channel. While the substrate is being processed, the controller causes a reduction in pressure in the gas-evacuation conduit downstream of the gas-evacuation port.

The apparatus also can include an exhaust pump connected to the HTG-supply conduit, wherein the exhaust pump is configured to reduce a pressure in the HTG-supply conduit. Such an apparatus desirably also includes a pressure sensor connected to the HTG-supply conduit, wherein the pressure sensor is configured to measure the pressure in the HTG-supply conduit.

Further with respect to such an apparatus, the gas-evacuation system also can include a gas-evacuation conduit connected to the gas-evacuation valve. With such a configuration, the controller is connected to the HTG-inlet valve and gas-evacuation valve. The controller closes the gas-evacuation valve after causing heat-transfer gas to be supplied through the HTG-inlet port to the channel. While the substrate is being processed, the controller causes reduction of the pressure in the gas-evacuation conduit downstream of the gas-evacuation valve.

According to another embodiment of a method, according to the invention, for holding a substrate, an electrostatic wafer chuck is provided that comprises an adhesion surface. The adhesion surface defines an HTG channel to which heat-transfer gas is supplied through an HTG-inlet valve and HTG-inlet conduit connecting the channel to an HTG supply. Gas is evacuated from the HTG channel through a gas-evacuation valve and a gas-evacuation conduit. At the time of performing the process on the substrate (electrostatically attached to the adhesion surface), the gas-evacuation valve and HTG-inlet valve are opened to supply heat-transfer gas to the channel. While performing the process on the substrate attached to the adhesion surface but after supplying the heat-transfer gas for a predetermined length of time, the gas-evacuation valve is closed. A vacuum is formed in the gas-evacuation conduit downstream of the gas-evacuation valve. The method also includes the step of closing the HTG-inlet valve and opening the gas-evacuation valve, with the vacuum in the gas-evacuation conduit, so as to evacuate the channel. After evacuating the channel, the processed substrate can be removed from the adhesion surface and exchanged for an unprocessed substrate.

According to yet another embodiment, a substrate-holding device according to the invention comprises a wafer chuck as summarized above. An HTG-supply system is connected to the HTG channel and configured to supply a heat-transfer gas to the channel. The device includes a cold trap connected to the HTG-supply system such that heat-transfer gas intended to enter the channel passes through the cold trap before entering the channel. The cold trap is configured to remove impurities from the heat-transfer gas as the gas passes through the cold trap. The cold trap can include an adsorbent for collecting the impurities, a vessel configured to contain a cooling substance at a temperature sufficient to at least liquefy impurities in the heat-transfer gas so that the impurities can be adsorb onto the adsorbent, and an exhaust system connected to the cold trap. The exhaust system comprises an exhaust duct, an exhaust valve, and an exhaust pump. The exhaust valve and exhaust pump are operable (e.g., as actuated by a controller) to isolate the cold trap from the channel and remove the adsorbed impurities from the adsorbent, respectively. The device also can include a recirculation conduit configured to recover heat-transfer gas passing through the channel and to direct the recovered heat-transfer gas to a location upstream of the cold trap so as to pass through the cold trap to the channel. The device also can include a bypass valve connected to the recirculation conduit, an HTG-inlet valve connected to the HTG-supply system. In such a configuration, a controller desirably is connected to the bypass valve, the HTG-inlet valve, the exhaust valve, and the exhaust pump. The controller is configured to operate the HTG-inlet valve relative to the exhaust pump so as to supply heat-transfer gas to the HTG channel, to operate the exhaust valve and exhaust pump relative to the HTG-inlet valve to remove heat-transfer gas from the HTG channel, and to operate the bypass valve to recirculate the heat-transfer gas.

The invention also encompasses wafer stages that include a wafer chuck according to any of the various embodiments thereof.

The foregoing and additional features and advantages of the invention will be more readily apparent from the following detailed description, which proceeds with reference to the accompanying drawings.

### BRIEF DESCRIPTION OF THE DRAWINGS

FIG. 1(A) is a schematic depiction (including an elevational section) of certain aspects of a charged-particle-beam (CPB) microlithography apparatus including a wafer chuck according to a first representative embodiment of the invention.

FIG. 1(B) is a block diagram of the heat-transfer-gas (HTG) inlet and evacuation-control system of the first representative embodiment.

FIG. 2 is an exemplary graph of the relationship of pressure inside HTG channels in the wafer chuck of the first representative embodiment during evacuating the HTG channels versus time required for evacuation of the HTG channels.

FIG. 3 is a flowchart of a wafer-exposure sequence using an apparatus according to the first representative embodiment.

FIG. 4 is a schematic depiction (including an elevational section) of certain aspects of a CPB microlithography apparatus according to second and third representative embodiments of the invention.

FIG. 5 is a schematic depiction (including an elevational section) of certain aspects of a CPB microlithography apparatus according to a fourth representative embodiment of the invention.

FIG. 6 is a flowchart of steps in a process for manufacturing a microelectronic device such as a semiconductor chip (e.g., IC or LSI), liquid-crystal panel, CCD, thin-film magnetic head, or micromachine, the process including performing microlithography using a microlithography apparatus according to the invention.

### DETAILED DESCRIPTION

The invention is described below in the context of representative embodiments, which are not to be regarded as limiting in any way. The embodiments are described in the context of using an electron beam as a representative charged particle beam. However, it will be understood that the general principles described herein are applicable with equal facility to use of another charged particle beam, such as an ion beam. Also, although normally not used in an optical microlithography apparatus (i.e., a microlithography apparatus employing light as an energy beam), a wafer chuck according to the invention can be incorporated into and used with ready facility in an optical microlithography apparatus.

First Representative Embodiment

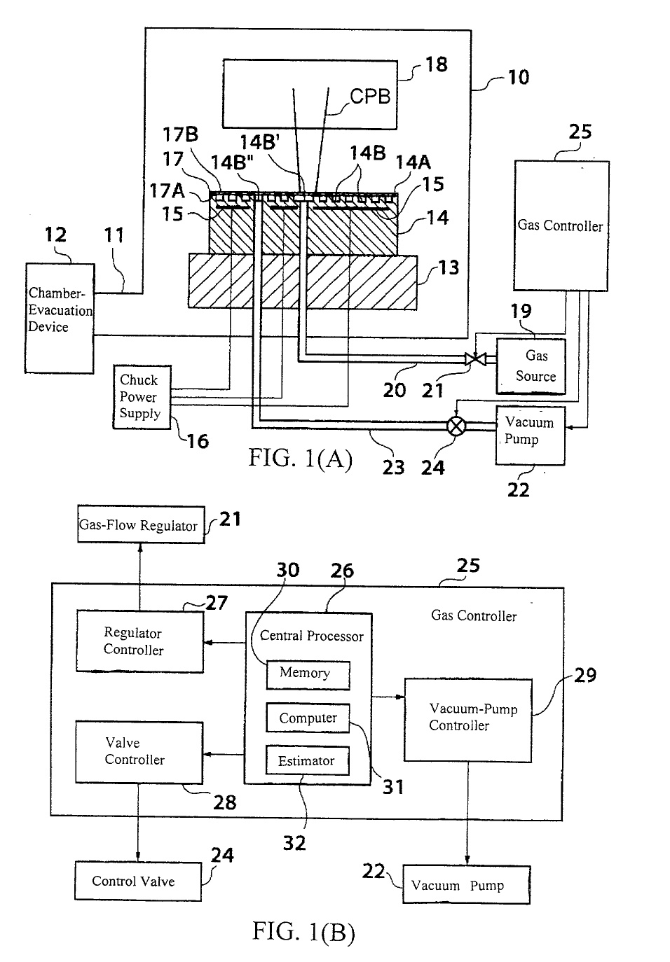

The first representative embodiment is depicted in FIGS. 1(A) and 1(B). FIG. 1(A) provides certain structural details (as shown in a schematic elevational section) of the wafer chuck and associated mechanisms, and FIG. 1(B) is a block diagram of the heat-transfer gas (HTG) inlet and evacuation-control system of the apparatus shown in FIG. 1(A). The apparatus shown in FIG. 1(A) includes a wafer stage 13 and a wafer chuck 14 mounted to the wafer stage 13. A wafer 17 is shown mounted to the wafer chuck 14. The wafer stage 13, wafer chuck 14 (with wafer 17), and exposure-optical system 18 are enclosed inside a vacuum chamber 10. The vacuum chamber 10 is connected to a chamber-evacuation device 12 (e.g., vacuum pump) via a duct 11. The chamber-evacuation device 12 evacuates the atmosphere inside the vacuum chamber 10 to a desired subatmospheric pressure (“vacuum”) and maintains the desired vacuum level inside the vacuum chamber 10.

The wafer stage 13 is configured to move back and forth between a wafer-exchange position and a wafer-exposure position. The wafer-exchange position is a position at which the wafer currently mounted to the wafer chuck 14 is removed and replaced with a new wafer. The wafer-exposure position is a position at which the wafer currently mounted to the wafer chuck 14 is exposed by microlithography. The wafer stage 13 (with wafer chuck 14) is situated inside the vacuum chamber 10. In FIG. 1(A), the wafer stage 13 is situated at the wafer-exposure position. The wafer chuck 14 is mounted to the upstream-facing (“top”) surface of the wafer stage 13. The wafer chuck 14 includes an “adhesion surface” 14A in which multiple channels 14B are formed. The channels 14B, typically formed by machining the adhesion surface 14A, extend “downward” in the figure. The channels 14B include a “center” channel 14B′ and a peripheral channel 14B″. The channels 14B are contiguous with each other and are intended for passage of heat-transfer gas therethrough. Hence, the channels 14B are termed “HTG channels.”

Also, beneath the adhesion surface 14A are situated multiple (three shown in FIG. 1(A)) electrodes 15 embedded in the thickness dimension of the wafer chuck 14. The electrodes 15 are connected electrically to a chuck power supply 16, situated outside the vacuum chamber 10. The chuck power supply 16 is configured to apply a voltage on the various electrodes 15. As the electrodes 15 are energized in such a manner, an electrostatic force is generated between the wafer chuck 14 and the wafer 17. The electrostatic force causes the “bottom” (downstream-facing) surface 17A of the wafer 17 to adhere to the adhesion surface 1 4A of the wafer chuck 14. Thus, the wafer chuck 14 can hold the wafer 17 at the wafer-exposure position at which a desired pattern can be exposed microlithographically on the “process surface” (upstream-facing, “top,” or “sensitive” surface) 17B of the wafer 17 using an energy beam. The energy beam typically is a charged particle beam such as an electron beam or ion beam, but alternatively can be a light beam such as an ultraviolet light beam or X-ray beam. The energy beam forms the pattern image on the process surface 17B of the wafer 17 by means of the exposure-optical system 18.

An HTG-inlet conduit 20 is connected to a “center” channel 14B′ in the adhesion surface 14A of the wafer chuck 14. The HTG-inlet conduit 20 is connected to a gas source 19 that provides a heat-transfer gas such as helium. A gas-flow regulator 21 controls the flow rate of heat-transfer gas as delivered by the gas source 19 to the conduit 20. Thus, the quantity of heat-transfer gas discharged into the HTG channels 14B in the chuck 14 is adjusted by controllably operating the gas-flow regulator 21, to maintain the gas pressure within the HTG channels 14B at a desired “target” pressure (e.g., 2.7 kPa (20 Torr) for helium). It is desirable that the pressure of the heat-transfer gas filling the HTG channels not exceed the target pressure to ensure maintenance of a proper balance between the electrostatic force holding the wafer to the wafer chuck and the pressure of the heat-transfer gas. Thus, the wafer is prevented from unexpectedly separating from the adhesion surface during wafer exposure. The heat-transfer gas discharged into the HTG channels 14B suppresses thermal expansion of the wafer 17 by dissipating heat from the wafer 17 into the wafer chuck 14.

A vacuum pump 22 is connected to the peripheral channel 14B″ via a gas-evacuation conduit 23. The gas-evacuation conduit 23 includes a control valve 24. By opening the control valve 24 and running the vacuum pump 22, the heat-transfer gas is evacuated from the HTG channels 14B in the wafer chuck 14, thereby reducing the pressure (“increasing” the “vacuum”) inside the HTG channels 14B to a desired level (e.g., 13 Pa (0.1 Torr) for helium).

The gas-flow regulator 21, vacuum pump 22, and control valve 24 are connected electrically to a gas controller 25 situated outside the vacuum chamber 10. The gas controller 25 controls the various operations of the gas-flow regulator 21, the vacuum pump 22, and the control valve 24.

As shown in FIG. 1(B), the gas controller 25 comprises a central processor 26, a regulator controller 27 (connected to the gas-flow regulator 21), a valve controller 28 (connected to the control valve 24), and vacuum-pump controller 29 (connected to the vacuum pump 22). The central processor 26 includes a memory 30, a computer 31 and an estimator 32. The central processor 26 inputs a respective drive signal to the regulator controller 27 at a specified time before commencing exposure of the wafer 17. The central processor 26 also stops input of the drive signal to the regulator controller 27 at a time estimated by the estimator 32, and simultaneously inputs respective drive signals to the valve controller 28 and the vacuum-pump controller 29. The regulator controller 27 receives the respective drive signal from the central processor 26 and initiates operation of the gas-flow regulator 21 according to the respective drive signal. The valve controller 28 receives the respective drive signal from the central processor 26 and opens the control valve 24 accordingly. The vacuum pump 29 receives the respective drive signal from the central processor 26 and operates the vacuum pump 22 accordingly.

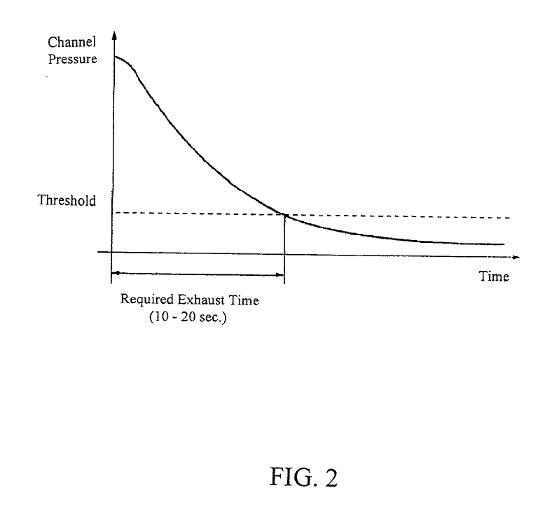

During operation of the vacuum pump 22, the subatmospheric pressure in the HTG channels 14B is related to the evacuation (exhaust) time (for evacuating the HTG channels 14B). The evacuation time, in turn, is a function of the respective transverse dimensions of the HTG channels 14B and HTG-inlet conduit 20, as well as the pumping performance of the vacuum pump 22, as shown in FIG. 2. Specifically, FIG. 2 is a graph of an exemplary relationship between the subatmospheric pressure inside the HTG channels 14B while the channels are being evacuated by the vacuum pump 22 and the time required for evacuating the channels to a desired threshold vacuum level. The graph of FIG. 2 can be used to determine the time necessary for evacuating the HTG channels 14B to the threshold vacuum level (required “exhaust” time). Typically, the time is 10 to 20 seconds.

The evacuation time determined from the graph of FIG. 2 is stored, in advance, in the memory 30 of the central processor 26. The time from completing exposure of the wafer 17 to the instant the wafer chuck 14, holding the processed wafer 17, has moved to the wafer-exchange position also is stored in advance in the memory 30. This latter time is determined from variables such as the size of the vacuum chamber 10 and the movement velocity of the wafer stage 13.

The computer 31 in the central processor 26 calculates the time required for microlithographically exposing the wafer 17 (i.e., required exposure time), based on the particular pattern to be transferred to the process surface 17B of the wafer 17. Based on the required exposure time, the estimator 32 estimates the time required, during wafer exposure, to evacuate the HTG channels 14B in the wafer chuck 14. Test results have shown that, for example, thermal expansion of the wafer 17 is negligible even if the HTG channels 14B are evacuated after exposure of the wafer 17 is 80% or more completed.

If the required evacuation time is substantially less than the required exposure time, it is desirable to commence evacuating the heat-transfer gas from the HTG channels 14B in advance of the time at which wafer-exchange commences. In this case, wafer exchange can be performed at the moment when the wafer chuck 14 holding the processed wafer 17 has been moved by the wafer stage 13 to the wafer-exchange position. On the other hand, if the required evacuation time is only slightly less than the required wafer-exposure time, it is desirable to commence evacuating the heat-transfer gas from the HTG channels 14B when exposure of the current wafer 17 is at least 80% completed. In this case as well, wafer exchange can be performed shortly after the wafer chuck 14 holding the processed wafer 17 has been moved by the wafer stage 13 to the wafer-exchange position. During evacuation of the heat-transfer gas, the pressure of the heat-transfer gas in the HTG channels 14B gradually decreases, accompanied by a corresponding decrease in the wafer-cooling ability of the heat-transfer gas. However, since wafer exposure nearly is completed, thermal expansion of the wafer is minimal and has virtually no adverse effect.

By way of example, consider a situation in which the required channel-evacuation time is 20% or less of the required wafer-exposure time (e.g., required channel-evacuation time is 15 seconds and the required wafer-exposure time is 120 seconds). In such a situation, the estimator 32, based on the required wafer-exposure time as calculated by the computer 31, estimates the required channel-evacuation time as the time occurring before the instant at which the chuck 14 holding the processed wafer 17 is moved by the wafer stage 13 to the wafer-exchange position. Consider now a situation in which the required channel-evacuation time is 20% or more of the required wafer-exposure time (e.g., required channel-evacuation time is 15 seconds and the required wafer-exposure time is 70 seconds). In such a situation, the estimator 32, based on the required wafer-exposure time as calculated by the computer 31, estimates the required channel-evacuation time as the time occurring before the instant at which exposure of the wafer 17 is 80% or more completed.

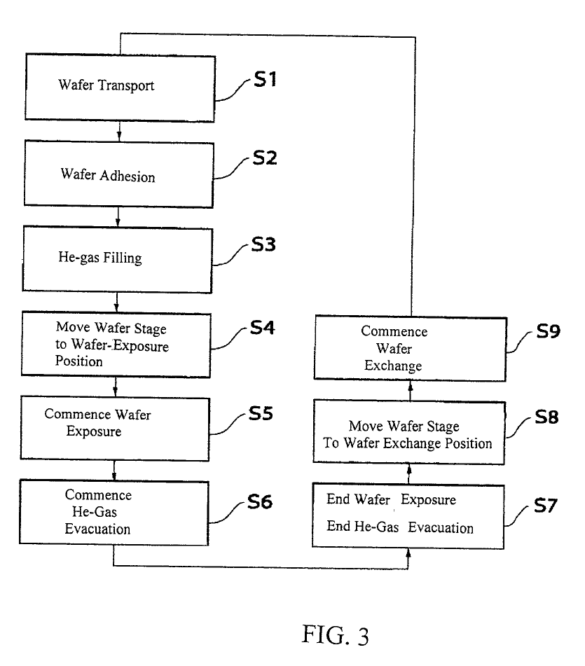

A wafer-exposure sequence according to this embodiment is shown, in block format, in FIG. 3. In step S1, the wafer 17 is transported into the vacuum chamber 10 to the wafer stage 13 situated at a wafer-exchange position. In step S2, the chuck power supply 16 applies a voltage on the various electrodes 15 in the wafer chuck 14. The applied voltage generates an electrostatic force between the wafer chuck 14 and the wafer 17, causing the wafer 17 to adhere to the adhesion surface 14A of the wafer chuck 14. In step S3, the central processor 26 inputs a respective drive signal to the regulator controller 27, which triggers the regulator controller 27 to actuate operation of the gas-flow regulator 21. As a result, helium gas (or other suitable heat-transfer gas) from the gas source 19 fills the HTG channels 14B in the adhesion surface 14A; meanwhile, the gas-flow regulator 21 maintains the gas pressure in the HTG channels 14B at a desired target value (e.g., 2.7 kPa). Heat in the wafer is dissipated into the wafer chuck 14 as the heat-transfer gas conducts the heat away from the wafer chuck 14. As a result, thermal expansion of the wafer 17 is suppressed. In step S4, the wafer stage 13 moves from the wafer-exchange position to the wafer-exposure position. Step S5 involves commencing exposure of the process surface 17B of the wafer 17 with the desired pattern using an energy beam EB. In step S6, the central processor 26 inputs respective drive signals to the valve controller 28 and the vacuum-pump controller 29, causing the control valve 24 to open and the vacuum pump 22 to operate. At this time, the central processor 26 stops inputting the respective drive signal to the regulator controller 27, thereby stopping operation of the gas-flow regulator 21. Thus, the HTG channels 14B in the adhesion surface 14A are evacuated by the vacuum pump 22.

If the required channel-evacuation time is 20% or less of the required wafer-exposure time, then the estimator 32 estimates the required channel-evacuation time as a period beginning before the wafer chuck 14, holding the processed wafer 17, moves to the wafer-exchange position. On the other hand, if the required channel-evacuation time is 20% or more of the required wafer-exposure time, then the estimator 32 estimates the channel-evacuation time as a time period beginning when exposure of the wafer 17 is 80% or more completed.

Continuing with the method of FIG. 3, in step S7, exposure of the wafer 17 is completed. At this time, evacuation of the HTG channels 14B in the adhesion surface 14A is completed and the pressure inside the HTG channels 14B is at the threshold level (e.g., 13 Pa for helium). Channel-evacuation is continued to offset effects of leakage. In step 8, the wafer stage 13 moves from the wafer-exposure position to the wafer-exchange position. At this time, since the pressure inside the HTG channels 14B has been reduced to the threshold level (e.g., 13 Pa for helium), the quantity of residual heat-transfer gas in the HTG channels 14B is extremely small. Consequently, any release of heat-transfer gas into the interior of the lens column, through which the energy beam EB passes, is slight. At this time, the processed wafer 17 is exchanged for a new wafer 17 (step S9).

In this embodiment, since the HTG channels 14B are evacuated sufficiently at the time movement of the stage 13 to the wafer-exchange position is completed, as explained above, exchange of the wafer 17 can be accomplished quickly at the instant the wafer stage 13 reaches the wafer-exchange position.

Second Representative Embodiment

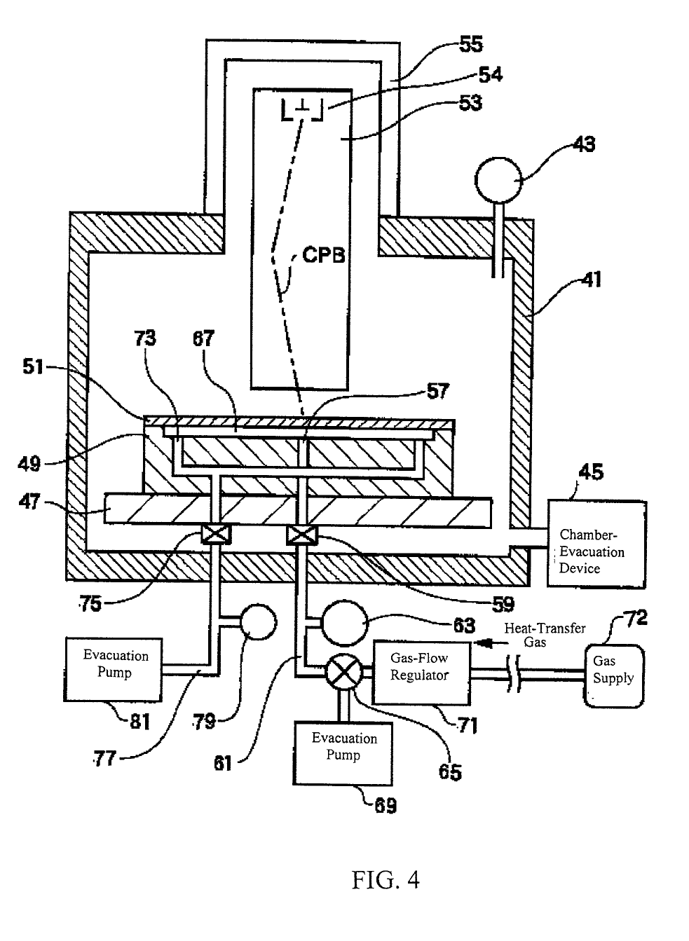

This embodiment is shown in FIG. 4, in which schematic elevational sections of a wafer stage 47, a wafer chuck 49, and wafer 51 are shown. The FIG. 4 apparatus includes a vacuum chamber including a charged-particle-beam (CPB) column 55 and a wafer chamber 41. A system of conduits for supplying heat-transfer gas and for evacuating the heat-transfer gas from the wafer chuck 49 is shown at the bottom of the figure. The CPB column 55 contains a CPB-optical system 53 that includes a CPB source 54 (e.g., electron gun). The wafer chamber 41 contains the wafer stage 47 and wafer chuck 49. A charged particle beam CPB emitted from the source 54 passes through the CPB-optical system 53 in which the beam is deflected, focused, and formed as required to form an image on the process surface of the wafer 51.

A chamber-evacuation device 45, including a vacuum pump, is connected at the lower right (in the figure) of the wafer chamber 41. The chamber-evacuation device 45 evacuates the interior of the wafer chamber 41 to a desired subatmospheric pressure (“vacuum”), as measured and indicated by a vacuum gauge 43. The chamber-evacuation device 45 maintains the interior of the wafer chamber 41 at a specified vacuum level (e.g., 1.3×10⁻³ Pa (10⁻⁵ Torr)).

The wafer chuck 49 is mounted on an upstream-facing surface of the wafer stage 47. The wafer stage 47 is configured to move inside the wafer chamber 41, including to and from a wafer-exchange position and a wafer-exposure position. The adhesion surface of the wafer chuck 49 defines a heat-transfer-gas (HTG) channel 67. The HTG channel 67 is filled with helium gas as a representative heat-transfer gas. Heat in the wafer 51 is dissipated into the wafer chuck 49 via the heat-transfer gas, thereby suppressing thermal expansion of the wafer 51.

Electrodes (not illustrated) are embedded inside the wafer chuck 49. By applying a voltage on the electrodes, an electrostatic force is generated between the wafer chuck 49 and the wafer 51, causing the downstream-facing surface of the wafer 51 to adhere to the adhesion surface of the wafer chuck 49.

To supply the heat-transfer gas, an HTG-inlet port 57 is provided at the center of the wafer chuck 49. The HTG-inlet port 57 extends through the “lower” portion of the wafer chuck 49 and through the wafer stage 47 to the “bottom” surface of the wafer stage 47. An HTG-inlet valve 59 is mounted on the HTG-inlet port 57 where the HTG-inlet port exits the wafer stage 47. An HTG-inlet duct 61 provides a gas connection to the HTG-inlet valve 59 through the wafer chamber 41. An HTG-inlet-duct pressure gauge or pressure sensor 63 is connected to the HTG-inlet duct 61. A gas-flow regulator 71 is connected via a three-way valve 65 to the HTG-inlet duct 61. An HTG supply 72 (e.g., gas cylinder for storing helium as a representative heat-transfer gas) is connected to and supplies the heat-transfer gas to the gas-flow regulator 71 and thus to the wafer chuck 49. Whenever the heat-transfer gas is supplied to the wafer chuck 49, the gas-flow regulator 71 controls the gas pressure, as measured by the HTG-inlet-duct pressure gauge 63, to a desired value. The target value for pressure inside the HTG channel 67 is, e.g., 1.3 kPa (10 Torr) for helium. The target value is determined with consideration given to a proper balance of the pressure with the electrostatic force between the wafer chuck 49 and the wafer 51.

An evacuation pump 69 is connected to the side port of the three-way valve 65. During evacuation of heat-transfer gas from the HTG channels 67, the three-way valve 65 is switched to connect the HTG-inlet duct 61 with the evacuation pump 69 (i.e., the gas-flow regulator 71 is isolated from the HTG-inlet duct 61), to achieve evacuation of the heat-transfer gas from the HTG-inlet duct 61.

With respect to the evacuation system for the heat-transfer gas, gas-evacuation ports 73 are provided in the wafer chuck 49 at the “bottoms” of the HTG channels 67. The gas-evacuation ports 73 converge to a single conduit inside the wafer chuck 49. The single conduit exits the “lower” portion of the wafer chuck 49 and extends through the wafer stage 47 to a gas-evacuation valve 75 mounted on the downstream side of the gas-evacuation port 73. The gas-evacuation valve 75 is mounted directly to the wafer stage 47. In the figure, a gas-evacuation duct 77 connects the gas-evacuation valve 75 to an evacuation pump 81. A gas-evacuation pressure gauge 79 is connected to the gas-evacuation duct 77 between the evacuation pump 81 and the gas-evacuation valve 75.

Whenever no wafer 51 is mounted on the wafer chuck 49, both the HTG-inlet valve 59 and the gas-evacuation valve 75 are closed. Upon placing a wafer 51, to be processed, on the adhesion surface of the wafer chuck 49, electrical current is supplied to the electrodes (not illustrated) in the wafer chuck to cause the wafer 51 to adhere to the adhesion surface. Next, the HTG channel 67 is filled with heat-transfer gas supplied from the gas supply 72 through the gas-flow regulator 71, the three-way valve 65, the HTG-inlet duct 61, the HTG-inlet valve 59, and the HTG-inlet port 57. At this time, the HTG-flow regulator 71 controls the rate of heat-transfer-gas flow while the gas pressure in the HTG channel 67 is monitored using the HTG-inlet-duct pressure gauge 63. Meanwhile, the evacuation pump 69 is shut off by the three-way valve 65 from the HTG-inlet duct 61.

After commencing exposure of the wafer 51, heat-transfer gas is supplied intermittently to the HTG channel 67 from the HTG-inlet duct 61 to compensate for any leakage of gas from the channel. Meanwhile, the gas-evacuation valve 75 remains closed during exposure, and the evacuation pump 81 is running continuously. At this time, a “vacuum” of about 1.3×10⁻¹ Pa (10⁻³ Torr) is created inside the gas-evacuation duct 77.

Completion of exposure and exchange of the wafer 51 is accomplished as follows. First, the HTG-inlet valve 59 is closed and the three-way valve 65 actuates to block off the gas-flow regulator 71 from the HTG-inlet duct 61 while opening the HTG-inlet duct 61 to the evacuation pump 69. The evacuation pump 69 is turned on. As the gas-evacuation valve 75 is opened, heat-transfer gas in the HTG channel 67 is evacuated rapidly by the action of the vacuum buffer established inside the gas-evacuation duct 77. After the HTG-inlet-duct pressure gauge 63 confirms that the pressure in the HTG-inlet duct 61 has dropped to a sufficiently low level, the HTG-inlet valve 59 is opened.

As mentioned above, the HTG-inlet valve 59 desirably is mounted on the wafer chuck 49 or the wafer stage 47. “Mounted on” in this context means “attached directly or near to.” Since the HTG-inlet valve 59 is thus situated at least near the wafer chuck 49, after the heat-transfer gas has been supplied to the HTG channel 67, the gas-evacuation valve 75 can be closed during the time that wafer processing, such as microlithographic exposure, is being performed, and a vacuum can be created downstream of the gas-evacuation duct 77. At completion of wafer processing, at the moment the gas-evacuation valve 75 is opened to evacuate the heat-transfer gas, the void in the evacuated gas-evacuation duct 77 serves as a “vacuum buffer” for the heat-transfer gas in the HTG channel 67. The buffer causes the heat-transfer gas in the HTG channel 67 to be evacuated rapidly. The amount of heat-transfer gas to be evacuated is limited to the amount of gas in conduits and other space on the area on the “chuck side” of the gas-evacuation valve 75. Using such a scheme, the heat-transfer gas is evacuated rapidly and wafer exchange can be accomplished very quickly, thereby improving throughput.

Third Representative Embodiment

In the second representative embodiment, the HTG-inlet valve 59 was left open during wafer exposure, and losses of heat-transfer gas due to gas leakage were supplemented continuously from the HTG-inlet duct 61. However, if gas leakage from the HTG channel 67 is not a problem during wafer exposure the HTG-inlet valve 59 can be left open during wafer exposure. Such a situation is addressed by the third representative embodiment. I.e., in the third representative embodiment, and referring further to FIG. 4, after the pressure inside the HTG channel 67 has reached a desired level, the HTG-inlet valve 59 is closed and the three-way valve 65 switches to the evacuation-pump 69 side. Also, a vacuum is created inside the HTG-inlet duct 61 to the same level as the vacuum inside the gas-evacuation duct 77 (approximately 1.3×10⁻¹ Pa (10⁻³ Torr) for helium.

At the instant that wafer exposure is completed, both the gas-evacuation valve 75 and the HTG-inlet valve 59 are opened, causing rapid evacuation of the heat-transfer gas from the HTG channel 67. Such rapid evacuation is facilitated by the action of vacuum buffers previously established inside both the gas-evacuation duct 77 and the HTG-inlet duct 61.

Fourth Representative Embodiment

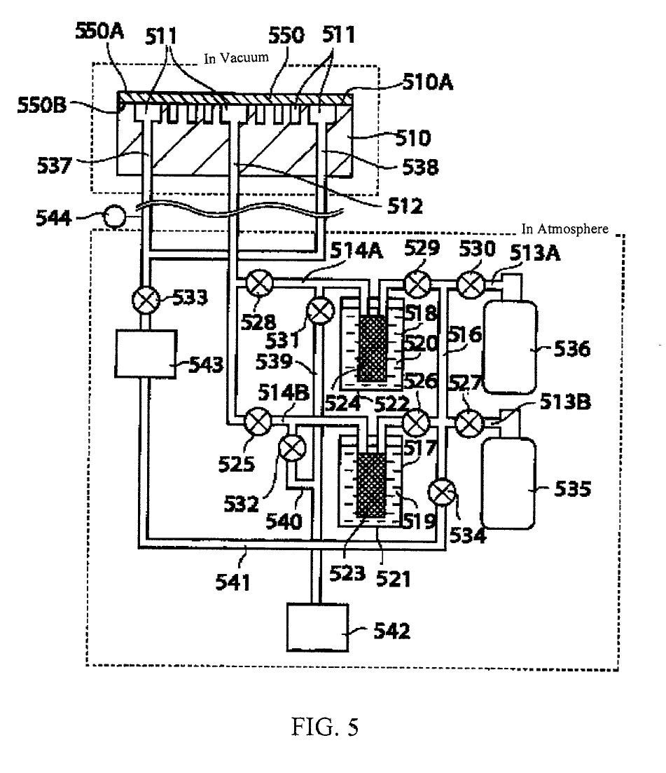

This embodiment is described with reference to FIG. 5, in which a wafer chuck 510 and cold traps 517, 518 are shown in schematic elevational section. All other components are shown as a schematic hydraulic diagram. The downstream-facing surface 550B of the wafer 550 is attracted by an electrostatic force from the wafer chuck 510 and is thereby adhered and secured to the adhesion surface (“top” surface) 510A of the wafer chuck 510. HTG channels 511 are defined in the adhesion surface 510A; the HTG channels 511 extend “downward” in the figure. An HTG-supply duct 512 is connected to the HTG channel 511 at the center of the adhesion surface 510A. Meanwhile, an end of each of gas-evacuation ducts 537, 538 is connected to a peripheral HTG channel 511 located at the perimeter of the adhesion surface 510A.

The HTG-supply duct 512 branches into two HTG-supply ducts 514A, 514B each including a respective valve 528, 525. Each HTG-supply duct 514A, 514B terminates at the respective cold trap 518, 517. The cold traps 517, 518 are connected via respective HTG-supply ducts 513B, 513A to respective HTG cylinders 535, 536. Hence, this embodiment includes two supply systems for heat-transfer gas.

Valves 529, 530 and valves 526, 527 are mounted approximately at mid-length of the respective HTG-supply ducts 513A, 513B. Opening the valves 529, 530 and 526, 527 feeds heat-transfer gas toward the respective cold traps 518, 517. A bypass duct 516 connects to the HTG-supply duct 513A between the valves 529, 530 and to the HTG-supply duct 513B between the valves 526, 527.

The cold traps 517, 518 are immersed in respective Dewar flasks 521, 522 filled, by way of example, with liquid nitrogen 519, 520 to maintain the cold traps 517, 518 at approximately the temperature of liquid nitrogen (approximately 77° K). The cold traps 517, 518 are filled with respective adsorbents 523, 524. The adsorbents 523, 524 can be, e.g., activated charcoal or the like, or a “molecular sieve” material such as that made by Wako Pure Chemistries, Ltd. (e.g., silver or copper powder or mesh).

Since the liquefaction point of helium is approximately 4° K at normal pressure, which is somewhat lower than the 77° K temperature of liquid nitrogen, helium gas can pass through the adsorbents 523, 524. On the other hand, since the vapor pressures of H₂O and CO₂ are extremely low at 77° K, H₂O and CO₂ solidify or at least liquefy when they reach the adsorbents 523, 524, and hence become trapped in the adsorbents. Consequently, impurities (e.g., H₂O and contaminant gases, etc.) in the heat-transfer gas reaching the cold traps 517, 518 are trapped, allowing only high-purity heat-transfer gas to be supplied to the HTG channels 511 in the wafer chuck 510.

Cleaning ducts 539, 540 branch via respective valves 531, 532 from respective portions of the HTG-supply ducts 514A, 514B downstream of the cold traps 517, 518. The cleaning ducts 539, 540 converge and are connected to a cleaning-evacuation system 542. Opening the valves 531, 532 allows the H₂O and contaminant gases, etc. that have been trapped by the respective cold traps 517, 518 to be extracted into the cleaning-evacuation system 542, thereby cleaning the cold traps 517, 518. Such cleaning normally is performed for either one or the other of the cold traps 517, 518. During cleaning, the liquid nitrogen 519, 520 in the respective Dewar flask 521, 522 is removed, thereby bringing the respective cold trap 517, 518 to room temperature. By periodically cleaning the cold traps in this manner, the contaminant-trapping capabilities of the cold traps 517, 518 are maintained.

The gas-evacuation ducts 537, 538 from the wafer chuck 510 are connected to a vacuum-evacuation system 543 via a valve 533. The vacuum-evacuation system 543 can be, e.g., a turbomolecular pump or dry pump. Heat-transfer gas in the HTG channels 511 can be evacuated by opening the valve 533 and generating a vacuum in the gas-evacuation ducts 537, 538 using the vacuum-evacuation system 543.

A pressure gauge 544 is connected to the gas-evacuation duct 537 and used for measuring the pressure of heat-transfer gas in the gas-evacuation duct 537. During processing of the wafer 550 (e.g., during microlithographic exposure of the wafer 550), the HTG-supply and gas-evacuation systems are regulated so that the pressure, as measured by the pressure gauge 544, is maintained at a specified value (e.g., 2.6 kPa for helium).

An HTG-resupply duct 541 is connected downstream of the vacuum-evacuation system 543. The HTG-resupply duct 541 is connected to the bypass duct 516 via a valve 534. By opening the valve 534 and valve 526 or valve 529, heat-transfer gas drawn into the vacuum-evacuation system 543 can be passed through a cold trap 517 or 518, respectively. Hence, H₂O and contaminant gases can be removed from the used heat-transfer gas to re-form high-purity heat-transfer gas therefrom. At this time, by opening the valve 525 or the valve 528, the re-formed high-purity heat-transfer gas can be supplied to the HTG channels 511 in the wafer chuck 510 and thus recycled. This scheme reduces the overall consumption rate of heat-transfer gas, thereby extending the lifetimes of the HTG supplies in the cylinders 535, 536.

To supply heat-transfer gas to the HTG channels 511 in the wafer chuck 510 from the cylinder 535, the valves 525, 526, 527 are opened. The valve 532 is closed so that heat-transfer gas that has passed through the cold trap 517 is not aspirated into the cleaning-evacuation system 542. Meanwhile, the valves 528, 529, 530 are opened to supply heat-transfer gas to the HTG channels 511 from the cylinder 536. The valve 531 is closed so that heat-transfer gas that has passed through the cold trap 518 is not aspirated into the cleaning-evacuation system 542. By opening the valves 527, 529 and closing the valve 526, heat-transfer gas from the cylinder 535 can be passed through the cold trap 518 and supplied to the HTG channels 511 during, for example, cleaning or performing maintenance on the other cold trap 517. As described above, trace amounts of H₂O, CO₂, etc., in the heat-transfer gas are trapped during passage of the heat-transfer gas through the cold trap 518, thereby supplying high-purity heat-transfer gas to the HTG channels 511.

As discussed above, the heat-transfer gas exiting the respective cylinder 535, 536 passes through the respective cold trap 517, 518, in which H₂O and contaminant gases in the heat-transfer gas are trapped. Thus, high-purity heat-transfer gas is supplied to the HTG channels 511 in the wafer chuck 510. Removing H₂O from the heat-transfer gas allows more rapid attainment of the desired vacuum level during evacuation of the heat-transfer gas from the HTG channels 511. Removing contaminant gases from the heat-transfer gas prevents the formation of contaminant precipitates, which, in turn, reduces the rate of contamination of the interior of the lens column and facilitates maintenance of a desired accuracy of the pattern transfer to the process surface of the wafer 550. Also, the rapid evacuation of the HTG channels 511 allows the wafer chuck 510 to be prepared quickly for wafer-exchange, thereby providing improved throughput. Again, each cold trap 517, 518 is maintained at a temperature at which the heat-transfer gas is not trapped, but at which impurities are trapped.

Also, the high-purity heat-transfer gas flowing through the HTG channels 511 dissipates heat from the wafer 550 into the wafer chuck 510, thereby suppressing thermal expansion of the wafer 550. This control of thermal expansion allows improved accuracy of pattern transfer to the process surface 550A of the wafer 550.

After use, the heat-transfer gas aspirated into the vacuum-evacuation system 543 can be passed through the cold traps 517, 518 via the HTG-resupply duct 541 to remove H₂O and contaminant gases from the used heat-transfer gas. Thus, high-purity heat-transfer gas is regenerated and “recycled.” The valves 525, 528 are opened to allow this regenerated high-purity heat-transfer gas to be resupplied to the HTG channels 511 in the wafer chuck 510.

Although helium gas is used as the heat-transfer gas in this embodiment, it will be understood that any of various other heat-transfer gases can be used. In any event, the heat-transfer gas must have thermal properties ensuring that the gas does not liquefy or solidify in the cold traps. In place of the cold traps 517, 518 described above, a system that purifies the heat-transfer gas using a cryopump, for example, alternatively can be used.

Fifth Representative Embodiment

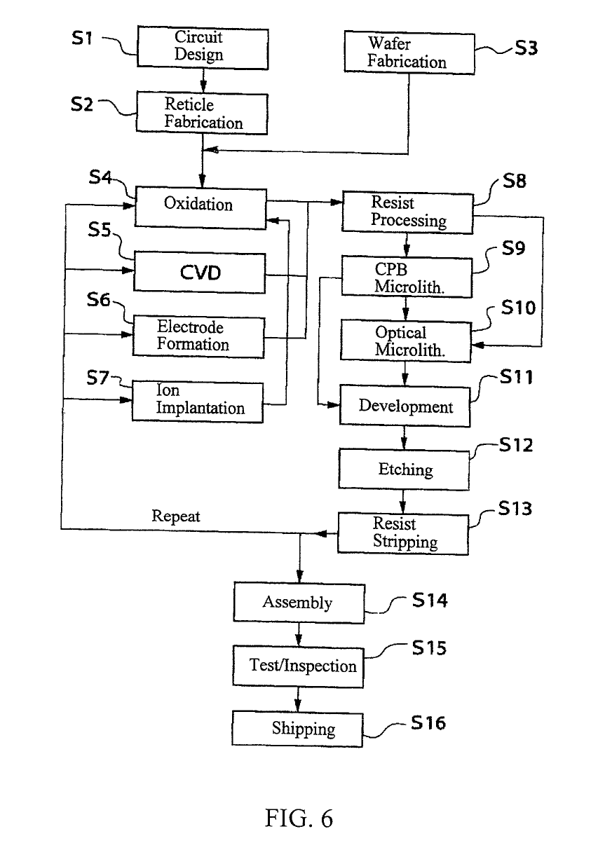

FIG. 6 is a flow chart of steps in a process for manufacturing a microelectronic device such as a semiconductor chip (e.g., an integrated circuit or LSI device), a display panel (e.g., liquid-crystal panel), charged-coupled device (CCD), thin-film magnetic head, micromachine, for example. In step 1, the circuit for the device is designed. In step 2, a reticle (“mask”) for the circuit is manufactured. In step 2, local resizing of pattern elements can be performed to correct for proximity effects or space-charge effects during exposure. In step 3, a wafer is manufactured from a material such as silicon.

Steps 4-13 are directed to wafer-processing steps, specifically “pre-process” steps. In the pre-process steps, the circuit pattern defined on the reticle is transferred onto the wafer by microlithography. Step 14 is an assembly step (also termed a “post-process” step) in which the wafer that has been passed through steps 4-13 is formed into semiconductor chips. This step can include, e.g., assembling the devices (dicing and bonding) and packaging (encapsulation of individual chips). Step 15 is an inspection step in which any of various operability and qualification tests of the device produced in step 14 are conducted. Afterward, devices that successfully pass step 15 are finished, packaged, and shipped (step 16).

Steps 4-13 also provide representative details of wafer processing. Step 4 is an oxidation step for oxidizing the surface of a wafer. Step 5 involves chemical vapor deposition (CVD) for forming an insulating film on the wafer surface. Step 6 is an electrode-forming step for forming electrodes on the wafer (typically by vapor deposition). Step 7 is an ion-implantation step for implanting ions (e.g., dopant ions) into the wafer. Step 8 involves application of a resist (exposure-sensitive material) to the wafer. Step 9 involves microlithographically exposing the resist using a charged particle beam to as to imprint the resist with the reticle pattern. In step 9, a CPB microlithography apparatus as described above can be used. Step 10 involves microlithographically exposing the resist using optical microlithography. Step 11 involves developing the exposed resist on the wafer. Step 12 involves etching the wafer to remove material from areas where developed resist is absent. Step 13 involves resist separation, in which remaining resist on the wafer is removed after the etching step. By repeating steps 4-13 as required, circuit patterns as defined by successive reticles are formed superposedly on the wafer.

According to the invention, as described above, evacuation of the space (channels) between the wafer and the wafer chuck can be initiated at an appropriate time during exposure of the wafer. Also, wafer exchange can be performed rapidly after the wafer chuck, holding a processed wafer, has moved to a wafer-exchange position. Hence, process throughput is improved.

In addition, whenever an evacuation valve is opened to evacuate the heat-exchange gas after completing processing of a wafer, the void in the gas-evacuation duct (that already has been evacuated) serves as a “vacuum buffer” for rapid evacuation of the heat-transfer gas from the HTG channels in the wafer chuck. Hence, at initiation of evacuation of heat-transfer gas from the HTG channels, the heat-transfer gas rapidly moves from the channels into the gas-evacuation duct, thereby rapidly evacuating the heat-transfer gas from the channels. Furthermore, the absolute amount of heat-transfer gas to be evacuated is limited to the amount present in the space on the chuck-side of the gas-evacuation valve. Therefore, throughput is increased because the heat-transfer gas can be evacuated rapidly at the time of wafer exchange, thereby allowing wafer exchange to be accomplished rapidly.

Furthermore, since impurities in the heat-transfer gas can be removed by using cold traps or the like before the gas is supplied to the HTG channels in the wafer chuck, according to this invention, evacuation of the channels can be completed rapidly. Also, processing can progress swiftly to wafer-exchange, allowing for improved throughput.

Whereas the invention has been described in connection with multiple representative embodiments, it will be understood that the invention is not limited to those embodiments. On the contrary, the invention is intended to encompass all modifications, alternatives, and equivalents as may be included within the spirit and scope of the invention, as defined by the appended claims.

What is claimed is:

1. A substrate-holding device for holding a substrate while a fabrication process is being performed on the substrate, the substrate-holding device comprising:
a wafer-chuck body defining an adhesion surface and comprising an electrostatic electrode, the adhesion surface being configured to contact a downstream-facing surface of a substrate being held by the substrate-holding device by an electrostatic force generated by the electrode;
the adhesion surface defining a channel configured, whenever the substrate is adhered to the adhesion surface by the electrostatic force, to provide a conduit for a heat-transfer gas that, when in the channel, contacts and removes heat from the downstream-facing surface of the substrate;
a gas-supply conduit configured to controllably conduct the heat-transfer gas from a source to the channel;
a gas-evacuation conduit configured to controllably conduct the heat-transfer gas from the channel; and
a controller configured to (i) cause the heat-transfer gas to flow through the channel from the gas-supply conduit during a predetermined time period when the sensitive substrate is being held on the adhesion surface, (ii) at a first predetermined time instant, commence execution of the fabrication process on the substrate being held on the adhesion surface, and (iii) at a second predetermined time instant relative to the fabrication process, commence evacuating the heat-transfer gas from the channel.

2. The substrate-holding device of claim 1, wherein the controller is further configured to determine, in advance of executing the fabrication process, an expected length of an evacuation time period required to evacuate the heat-transfer gas from the channel, and to set the second predetermined time instant based on the determined expected length of the evacuation time period.

3. The substrate-holding device of claim 2, wherein the controller is further configured to determine the second predetermined time instant as occurring before commencing an exchange, on the adhesion surface, of a new substrate for an already processed substrate.

4. The substrate-holding device of claim 1, wherein the controller is further configured to establish the second predetermined time instant as occurring at an instant when the fabrication process executed on the substrate on the adhesion surface is at least 80% complete.

5. The substrate-holding device of claim 1, wherein:
the heat-transfer gas is helium; and
the controller is further configured to establish a target pressure of the heat-transfer gas in the channel of no greater than 2.7 kPa (20 Torr).

6. The substrate-holding device of claim 1, wherein the fabrication process is an exposure process.

7. A substrate-processing apparatus, comprising the substrate-holding device of claim 1.

8. A microlithography apparatus, comprising:
an exposure-optical system situated and configured to form an image, on a sensitive substrate, of a pattern using an energy beam;
a wafer chuck comprising an adhesion surface defining a channel, the wafer chuck being situated relative to the exposure-optical system and configured to hold, as the sensitive substrate is being exposed by the energy beam, a downstream-facing surface of the sensitive substrate in contact with the adhesion surface;
a gas-supply conduit configured to controllably conduct a heat-transfer gas from a source to the channel as the sensitive substrate is being held on the adhesion surface, so as to cause the heat-transfer gas to flow through the channel and contact the downstream-facing surface;
a gas-evacuation conduit configured to controllably conduct the heat-transfer gas from the channel; and
a controller configured to (i) cause the heat-transfer gas to flow through the channel from the gas-supply conduit during a predetermined time period when the sensitive substrate is being held on the adhesion surface, (ii) at a first predetermined time instant, commence exposure of the sensitive substrate being held on the adhesion surface, and (iii) at a second predetermined time instant relative to the exposure, commence evacuating the heat-transfer gas from the channel.

9. The microlithography apparatus of claim 8, further comprising a vacuum chamber enclosing and providing a subatmospheric-pressure environment for the exposure-optical system and the wafer chuck.

10. The microlithography apparatus of claim 8, wherein the controller is further configured to determine, in advance of the exposure, an expected length of an evacuation time period required to evacuate the heat-transfer gas from the channel, and to set the second predetermined time instant based on the determined expected length of the evacuation time period.

11. The microlithography apparatus of claim 10, wherein the controller is further configured to determine the second predetermined time instant as occurring before commencing an exchange, on the wafer chuck, of a new substrate for an already-exposed substrate.

12. The microlithography apparatus of claim 8, wherein the controller is further configured to establish the second predetermined time instant as occurring at an instant when microlithographic exposure of the substrate on the wafer chuck is at least 80% complete.

13. The microlithography apparatus of claim 8, wherein:
the heat-transfer gas is helium; and
the controller is further configured to establish a target pressure of the heat-transfer gas in the channel of no greater than 2.7 kPa (20 Torr).

14. In a method for microlithographically exposing a pattern onto a sensitive substrate using an energy beam passing through a projection-optical system that forms an image of the pattern on the sensitive substrate, a method for reducing exposure-induced thermal deformation of the substrate, comprising:
providing a wafer chuck comprising an adhesion surface defining a channel, the channel being enclosable by a downstream-facing surface of a substrate being held on the adhesion surface;
mounting a sensitive substrate to the adhesion surface such that the downstream-facing surface of the substrate contacts the adhesion surface and encloses the channel;
introducing a heat-transfer gas into the channel such that the heat-transfer gas flowing through the channel contacts the downstream-facing surface of the substrate;
commencing exposure of the sensitive substrate mounted to the wafer chuck;
determining and setting an appropriate time instant, during the exposure, in which to commence evacuation of the heat-transfer gas from the channel in preparation for wafer-exchange; and
at the set time instant, commencing evacuation of the heat-transfer gas from the channel.

15. A wafer chuck for holding a substrate as a process is being performed on the sensitive substrate, the wafer chuck comprising:
an adhesion surface configured to contact a downstream-facing surface of the substrate whenever the substrate is mounted to the wafer chuck, the adhesion surface defining a channel that is enclosed whenever a sensitive substrate is mounted to the wafer chuck;
an electrode situated and configured to attract the sensitive substrate by electrostatic attraction such that the substrate is held on the wafer chuck with the downstream-facing surface contacting the adhesion surface, thereby enclosing the channel;
a heat-transfer-gas (HTG)-inlet port situated and configured to introduce a heat-transfer gas into the channel to contact with the downstream-facing surface of the substrate mounted to the adhesion surface;
a gas-evacuation port situated and configured to allow evacuation of heat-transfer gas from the channel; and
a valve mounted to the wafer chuck, the valve being configured to open and close at least one of the inlet port and the evacuation port.

16. The wafer chuck of claim 15, wherein the process is an exposure process.

17. The wafer chuck of claim 15, further comprising a controller connected to the valve and configured to open and close the valve as required to controllably cause heat-transfer gas to flow through the channel and to stop flow of heat-transfer gas through the channel.

18. A substrate-processing apparatus, comprising the wafer chuck of claim 15.

19. In a microlithography apparatus for exposing a pattern onto a sensitive substrate, a device for holding the sensitive substrate as the pattern is being exposed onto the sensitive substrate, the substrate-holding device comprising:
a movable wafer stage; and
a wafer chuck mounted to the wafer stage, the wafer chuck comprising (a) an adhesion surface configured to contact a downstream-facing surface of the substrate whenever the substrate is mounted to the wafer chuck, the adhesion surface defining a channel that is enclosed whenever a sensitive substrate is mounted to the wafer chuck; (b) a heat-transfer-gas inlet port situated and configured to introduce a heat-transfer gas into the channel to contact the downstream-facing surface of the substrate mounted to the adhesion surface; (c) a heat-transfer-gas evacuation port situated and configured to allow evacuation of heat-transfer gas from the channel; and (d) a valve mounted to the wafer chuck, the valve being configured to open and close at least one of the inlet port and the evacuation port.

20. A wafer-processing apparatus, comprising:
a vacuum chamber configured to be evacuated so as to reduce a pressure inside the vacuum chamber;
a movable wafer stage situated inside the vacuum chamber; and
a wafer chuck mounted to the wafer stage, the wafer chuck comprising (a) an adhesion surface configured to contact a downstream-facing surface of the substrate mounted to the wafer chuck, the adhesion surface defining a heat-transfer-gas (HTG) channel; (b) an electrode situated and configured to attract the sensitive substrate by electrostatic attraction such that the substrate is held on the wafer chuck with the downstream-facing surface contacting the adhesion surface and enclosing the HTG channel; (c) an HTG-inlet port situated and configured to introduce a heat-transfer gas into the channel to contact with the downstream-facing surface of the substrate mounted to the adhesion surface; (d) a gas-evacuation port situated and configured to allow evacuation of gas from the channel; and (e) a first valve mounted to the wafer chuck, the valve being configured to open and close at least one of the HTG-inlet port and the gas-evacuation port.

21. The apparatus of claim 20, wherein the first valve is configured to open and close the HTG-inlet port, the apparatus farther comprising an HTG source connected via an HTG-supply conduit to the HTG-inlet port.

22. The apparatus of claim 21, further comprising an exhaust pump connected to the HTG-supply conduit, the exhaust pump being configured to reduce a pressure in the HTG-supply conduit.

23. The apparatus of claim 22, further comprising a pressure sensor connected to the HTG-supply conduit, the pressure sensor being configured to measure the pressure in the HTG-supply conduit.

24. The apparatus of claim 22, further comprising a controller connected to the first valve, the exhaust pump, and the pressure sensor, the controller being configured to controllably actuate the first valve to introduce the heat-transfer gas into the channel when needed to remove heat from the substrate, and to actuate the exhaust pump to draw the heat-transfer gas from the channel in anticipation of substrate-exchange.

25. The apparatus of claim 21, further comprising a pressure sensor connected to the HTG-supply conduit, the pressure sensor being configured to measure a pressure in the HTG-supply conduit.

26. The apparatus of claim 21, wherein the first valve is associated with the HTG-inlet port, the wafer chuck further comprising a second valve associated with the gas-evacuation port.

27. The apparatus of claim 26, further comprising:
a gas-evacuation conduit connected to the gas-evacuation port; and
a controller connected to the first and second valves, the controller being configured to close the second valve after supplying heat-transfer gas through the HTG-inlet port to the channel and, while processing the substrate, reducing a pressure in the gas-evacuation conduit downstream of the gas-evacuation port.

28. A microlithography apparatus, comprising:
a projection-optical system situated and configured to form an image, carried by an energy beam, on a sensitive substrate;
a wafer chamber situated relative to the projection-optical system and configured to maintain the sensitive substrate at a subatmospheric pressure as the image is being formed on the sensitive substrate by the energy beam;
a movable wafer stage situated inside the wafer chamber;
a wafer chuck mounted on the wafer stage, the wafer chuck comprising an adhesion surface and being configured to attract the sensitive substrate with electrostatic force, thereby causing a downstream-facing surface of the substrate to adhere to the adhesion surface, the adhesion surface defining a heat-transfer-gas (HTG) channel configured such that a heat-transfer gas passing through the HTG channel contacts the downstream-facing surface of the substrate on the adhesion surface;
an HTG-supply system connected via an HTG-inlet valve to the HTG channel and configured to introduce the heat-transfer gas from an HTG supply into the channel;
a gas-evacuation system connected via a gas-evacuation valve to the HTG channel and configured to draw the heat-transfer gas from the channel; and
wherein at least one of the HTG-inlet valve and gas-evacuation valve is mounted on the wafer stage or wafer chuck.

29. The apparatus of claim 28, wherein the HTG-supply system comprises:
an HTG-inlet port connecting the HTG-inlet valve to the channel; and
an HTG-supply conduit connecting the HTG supply to the HTG-inlet valve.

30. The apparatus of claim 29, further comprising an exhaust pump connected to the HTG-supply conduit, the exhaust pump being configured to reduce a pressure in the HTG-supply conduit.

31. The apparatus of claim 30, further comprising a pressure sensor connected to the HTG-supply conduit, the pressure sensor being configured to measure the pressure in the HTG-supply conduit.

32. The apparatus of claim 31, wherein the gas-evacuation system further comprises:
a gas-evacuation conduit connected to the gas-evacuation valve; and
a controller connected to the HTG-inlet valve and gas-evacuation valve, the controller being configured to close the gas-evacuation valve after supplying heat-transfer gas through the HTG-inlet port to the channel and, while exposing the sensitive substrate, reducing a pressure in the gas-evacuation conduit downstream of the gas-evacuation valve.

33. In a method for performing a process on a substrate, a method for holding the substrate, comprising:
(a) providing an electrostatic wafer chuck comprising an adhesion surface defining a heat-transfer gas channel to which heat-transfer gas is supplied through a heat-transfer-gas (HTG)-inlet valve and HTG-inlet conduit connecting channel to an HTG supply, and from which gas is evacuated through a gas-evacuation valve and a gas-evacuation conduit;
(b) electrostatically attaching the substrate to the adhesion surface;
(c) at time of performing the process on the substrate attached to the adhesion surface, opening the gas-evacuation valve and the HTG-inlet valve to supply heat-transfer gas to the channel; and
(d) while performing the process on the substrate attached to the adhesion surface but after supplying the heat-transfer gas for a predetermined length of time, closing the gas-evacuation valve and applying a vacuum in the gas-evacuation conduit downstream of the gas-evacuation valve.

34. The method of claim 33, further comprising the steps, before step (b), of:
mounting the wafer chuck on a wafer stage; and
mounting at least one of the HTG-inlet valve and gas-evacuation valve on the wafer stage or wafer chuck;

35. The method of claim 33, further comprising the step, after step (d), of closing the HTG-inlet valve and opening the gas-evacuation valve, with the vacuum in the gas-evacuation conduit, so as to evacuate the channel.

36. The method of claim 35, further comprising the step, after evacuating the channel, of removing the processed substrate from the adhesion surface and exchanging the processed substrate for an unprocessed substrate.

37. The method of claim 33, wherein the process is an exposure process.

38. A substrate-holding device, comprising:
a wafer chuck comprising an adhesion surface and a heat-transfer-gas (HTG) channel;
an HTG-supply system connected to the channel and configured to supply a heat-transfer gas to the channel; and
a cold trap connected to the HTG-supply system such that heat-transfer gas intended to enter the channel passes through the cold trap before entering the channel, the cold trap being configured to remove impurities from the heat-transfer gas as the gas passes through the cold trap.

39. The substrate-holding device of claim 38, wherein the cold trap further comprises:
an adsorbent for collecting the impurities;
a vessel configured to contain a cooling substance at a temperature sufficient to at least liquefy impurities in the heat-transfer gas so that the impurities can be adsorb onto the adsorbent; and
an exhaust system connected to the cold trap, the exhaust system comprising an exhaust duct, an exhaust valve, and an exhaust pump, the exhaust valve and exhaust pump being controllably operable to isolate the cold trap from the channel and remove the adsorbed impurities from the adsorbent, respectively.

40. The substrate-holding device of claim 39, further comprising a recirculation conduit configured to recover heat-transfer gas passing through the channel and to direct the recovered heat-transfer gas to a location upstream of the cold trap so as to pass through the cold trap to the channel.

41. The substrate-holding device of claim 40, further comprising:
a bypass valve connected to the recirculation conduit;
an HTG-inlet valve connected to the HTG-supply system; and
a controller connected to the bypass valve, the HTG-inlet valve, the exhaust valve, and the exhaust pump, the controller being configured to operate the HTG-inlet valve relative to the exhaust pump so as to supply heat-transfer gas to the HTG channel, to operate the exhaust valve and exhaust pump relative to the HTG-inlet valve to remove heat-transfer gas from the HTG channel, and to operate the bypass valve to recirculate the heat-transfer gas.

42. A substrate-processing apparatus, comprising the substrate-holding device of claim 38.

43. A microelectronic-device fabrication process, comprising the steps of:
(a) preparing a wafer;
(b) processing the wafer; and
(c) assembling devices on the wafer formed during steps (a) and (b), wherein step (b) comprises the steps of (i) applying a resist to the wafer; (ii) exposing the resist; and (iii) developing the resist; and step (ii) comprises providing a charged-particle-beam (CPB) microlithography apparatus as recited in claim 7; and using the CPB microlithography apparatus to expose the resist with the pattern defined on the reticle.

44. A microelectronic device produced by the method of claim 43.

45. A microelectronic-device fabrication process, comprising the steps of:
(a) preparing a wafer;
(b) processing the wafer; and
(c) assembling devices on the wafer formed during steps (a) and (b), wherein step (b) comprises the steps of (i) applying a resist to the wafer; (ii) exposing the resist; and (iii) developing the resist; and step (ii) comprises providing a charged-particle-beam (CPB) microlithography apparatus as recited in claim 28; and using the CPB microlithography apparatus to expose the resist with the pattern defined on the reticle.

46. A microelectronic device produced by the method of claim 45.
